(19) United States
(12) Patent Application Publication
(10) Pub. No.: US 2012/0113730 A1
(43) Pub. Date: May 10, 2012

(54) RAM MEMORY ELEMENT WITH ONE TRANSISTOR

(75) Inventors: Sorin Ioan Cristoloveanu, Seyssinet (FR); Noel Rodriguez, Armilla(Granada) (ES); Francisco Gamiz, Armilla(Granada) (ES)

(73) Assignees: Centre National de la Recherche Scientifique, Paris Cedex 16 (FR); Universiadad de Granada, Armilla ( Granada) (ES)

(21) Appl. No.: 13/264,203

(22) PCT Filed: Apr. 13, 2010
(86) PCT No.: PCT/FR2010/050716

§ 371 Date: Jan. 18, 2012

(30) Foreign Application Priority Data
Apr. 15, 2009 (FR) 0952452

(51) Int. Cl. G11C 7/00; H01L 29/772

(52) U.S. Cl. 365/189.011; 257/347; 257/E29.242

(57) ABSTRACT

A memory element includes a MOS transistor having a drain, a source and a body region covered by an insulated gate, wherein the thickness of the body region is divided into two distinct regions separated by a portion of an insulating layer extending parallel to the plane of the gate.

### FIELD OF THE INVENTION

The present invention relates to a single-transistor RAM cell.

### DISCUSSION OF PRIOR ART

Historically, DRAM cells have been formed of an assembly comprising a MOS transistor and a capacitor. As integrated circuits have miniaturized, it has been possible to decrease the dimensions of MOS transistors, and the issue has been to decrease the capacitor size. To overcome this difficulty, memory cells formed of a single transistor, with no capacitor, have been provided, the MOS transistor having its bulk insulated by a junction, or its bulk insulated by an insulator in semiconductor-on-insulator (SOI) or semiconductor-on-nothing (SON) technologies. In such memory cells, the memorization corresponds to a charge storage in the transistor. This has resulted in an increased miniaturization of DRAM cells. However, the various known capacitor-less memory cells generally suffer from one at least of the following disadvantages: limited retention time, high consumption, low differentiation between the two storage states, complexity of control, use of two gates, low operating speed, impossibility of decreasing the thickness of the transistor bulk, which must ensure the simultaneous presence of electrons and holes, and/or difficulty of manufacturing.

### SUMMARY

Thus, an object of the invention is to provide a capacitor-less single-transistor RAM cell, which overcomes at least some of the disadvantages of known single-transistor memory cells.

Thus, an embodiment of the present invention provides a memory cell formed of a MOS transistor having a drain, a source, and a bulk region coated with an insulated gate, wherein the thickness of the bulk region is divided in two distinct regions separated by an insulated layer portion extending parallel to the gate plane.

According to an embodiment of the present invention, the two distinct regions have the same conductivity type.

According to an embodiment of the present invention, the two distinct regions have opposite conductivity types.

According to an embodiment of the present invention, the memory cell is formed from an SOI structure.

According to an embodiment of the present invention, the memory cell is formed from a FINFET structure.

According to an embodiment of the present invention, the insulating layer portion has a thickness approximately ranging from 1 to 10 nanometers, preferably from 1 to 3 nanometers.

According to an embodiment of the present invention, the bulk region closest to the gate has a thickness ranging from 5 to 50 nm, preferably from 5 to 20 nm.

According to an embodiment of the present invention, the memory cell further comprises a second insulated gate under the bulk region.

According to an embodiment of the present invention, the MOS transistor is insulated by an insulating layer.

According to an embodiment of the present invention, the MOS transistor is formed directly on a substrate having a conductivity type opposite to that of its drain/source.

According to an embodiment of the present invention, the bulk region comprises a third region separated from the above-mentioned two distinct regions by an insulating layer portion extending parallel to the gate plane and substantially having the same extension as the insulating layer portion extending between the first two distinct regions, and a second gate is arranged in front of the third distinct region, opposite to the first gate.

In the case where the source voltage is considered as the reference voltage and the source and drain regions are of type N, the invention provides a method of use comprising, in any order, the steps of:

writing of a 1: application of a positive voltage to the drain and, during the application of this positive voltage, application of a short positive voltage to the gate,

writing of a 0: application of a very slightly positive, zero, or negative voltage to the drain and application of a positive voltage to the gate,

reading: application of a negative voltage to the gate and of a slightly positive voltage to the drain, and

holding: application of a negative voltage to the gate and of a slightly positive or zero voltage to the drain.

In the case where the source voltage is considered as the reference voltage and the source and drain regions are of type N, and where the memory cell is a four-state memory cell with three bulk regions, the invention provides a method of use comprising, in any order, the steps of:

writing of a state (11): application of a positive voltage to the drain and, during the application of this positive voltage, application of a short positive voltage to the two gates,

writing of a state (00): application of a very slightly positive, zero, or negative voltage to the drain and application of a positive voltage to the two gates,

writing of a state (01) or (10): application of a positive voltage on the drain and, during the application of this positive voltage, application of a short positive voltage to one of the gates, then application of a very slightly positive, zero, or negative voltage to the drain, and application of a positive voltage to the other gate,

reading: application of a negative voltage on the gates and of a slightly positive voltage on the drain, and

holding: application of a negative voltage on the gates and of a slightly positive or zero voltage on the drain.

### BRIEF DESCRIPTION OF THE DRAWINGS

The foregoing and other objects, features, and advantages of the present invention will be discussed in detail in the following non-limiting description of specific embodiments in connection with the accompanying drawings, among which:

FIG. 1 is a simplified cross-section view of a memory cell according to an embodiment of the present invention;

FIGS. 2A and 2B illustrate the writing of a 1 into a memory cell according to an embodiment of the present invention;

FIG. 3 illustrates the writing of a 0 into a memory cell according to an embodiment of the present invention;

FIGS. 4A and 4B illustrate the reading, respectively of a 0 and of a 1, from a memory cell according to an embodiment of the present invention;

FIGS. 5A, 5B, and 5C illustrate voltages applied, respectively for the writing of a 1, the writing of a 0, and the reading in a memory cell according to an embodiment of the present invention;

FIGS. 6A to 6D are simplified cross-section views illustrating successive steps of an example of the manufacturing of a memory cell of the type in FIG. 1;

FIGS. 7A and 7B are simplified cross-section and perspective views of variations of a memory cell according to the present invention;

FIG. 8 shows another variation of a memory cell according to an embodiment of the present invention; and

FIG. 9 is a simplified cross-section and perspective view of another variation of a memory cell according to an embodiment of the present invention.

For clarity, the same elements have been designated with the same reference numerals in the different drawings and, as usual in the representation of integrated circuits, the various drawings are not to scale.

### DETAILED DESCRIPTION

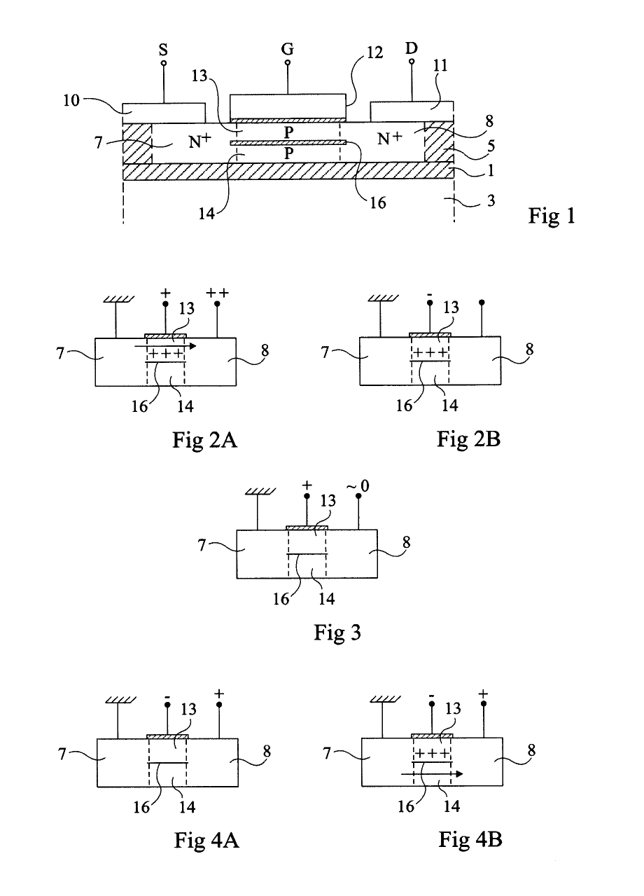

FIG. 1 is a cross-section view illustrating a capacitor-less memory cell. This memory cell comprises a MOS transistor formed on an insulating layer 1 laid on a support 3, generally, a silicon wafer. The area taken up by the MOS transistor, or active area, is delimited by an insulating periphery 5. The MOS transistor comprises heavily-doped source and drain regions of a first conductivity type 7 and 8 separated by a lightly-doped bulk region of the second conductivity type. In the following, it will be considered that the first conductivity type is type N and that the second conductivity type is type P, although this should not be considered as limiting. The source and drain regions are respectively solid with a source metallization 10 and with a drain metallization 11 connected to source and drain terminals S and D. The bulk portion of the transistor is topped with an insulated gate 12 connected to a gate terminal G. The thickness of the bulk region is divided in an upper bulk region 13 on the side of gate 12 and a lower bulk region 14 in the vicinity of insulating layer 1. The upper and lower bulk regions are separated by an insulating layer 16.

The structure of FIG. 1 will preferably be formed by using technologies enabling to obtain layer thicknesses with an accuracy better than 5 nm, preferably on the order of one nm. Technologies in which the lateral dimensions can be defined with minimum values lower than 50 nm will also be selected. In such conditions, as an example only, it may be chosen to form a structure in which the total transistor thickness is smaller than 100 nm, the upper bulk region having a thickness ranging from 5 to 50 nm, preferably close to 10 nm, and the lower bulk region having a thickness ranging from 5 to 50 nm, the upper bulk region and the lower bulk region being separated by an insulating layer 16 having a thickness ranging from 1 to 10 nm, for example, on the order of 3 nm. The channel length of the transistor will preferably be smaller than 65 nm, for example 35 nm.

The way in which the structure of FIG. 1 can be used as a memory cell will now be described in relation with FIGS. 2 to 4.

FIGS. 2A and 2B illustrates steps of writing of a 1 into the memory cell of FIG. 1. In the following, source S will be assumed to be permanently connected to a reference voltage which is designated, for simplicity, as being the ground.

To write a 1, as illustrated in FIG. 2A, a relatively high positive voltage, for example from 1 to 3 volts, is first applied to the transistor drain, and the gate is set to a positive voltage for a short time, while the positive voltage is applied to the drain. As a result, a channel region is formed in the upper bulk region (and not in the lower bulk region which is too distant from the gate) and electrons flow from the source to the drain. Given that the drain-source potential difference is selected to be relatively high, these electrons will create, by impact, electron-hole pairs in the upper bulk region. The created electrons take part in the current flow and the holes remain in the upper bulk region. If the current flow between source and drain is abruptly interrupted (FIG. 2B), by switching the gate to a negative voltage before switching the drain, holes designated by signs + in FIGS. 2A and 2B will remain in upper bulk region 13.

FIG. 3 illustrates the writing of a 0 into the memory cell. Again, the gate is made positive, but this time, drain 8 is connected to a slightly positive, zero, or even negative voltage. Then, the source-drain potential difference is insufficient to provide the creation of electron-hole pairs and, due to the electrostatic biasing created by the gate in upper bulk region 13, the holes that may be present in this upper bulk region will be drained off towards the drain and/or the source. Thus, the states of FIG. 2B and of FIG. 3 can be differentiated by the fact that in a case (writing of a 1), holes are stored in upper bulk region 13 and that in the second case (writing of a 0), no charge is stored in this upper bulk region.

FIGS. 4A and 4B respectively illustrate the reading of a 0 and the reading of a 1 from the memory cell of FIG. 1. In read (or retention) phase, a negative voltage is maintained on the gate and a slightly positive voltage is maintained in the drain.

As illustrated in FIG. 4A, in the case where a 0 has been stored, that is, no charge is stored in upper bulk region 13, the transistors in parallel sharing a same drain and a same source are both off: no current flows through the transistor corresponding to the upper bulk region since the gate is negative, and there is no reason for current to flow through the transistor corresponding to the lower bulk region since nothing is capable of creating an electron channel therein.

However, as illustrated in FIG. 4B, in the case where a 1 has been written, that is, positive charges are stored in upper bulk region 13, no current flows through the transistor corresponding to this upper bulk region since the gate is negative and no electron channel region is created in this upper bulk region. However, the positive charges stored in the upper bulk region induce by electrostatic coupling a channel region in the lower bulk region and a current will flow through the transistor having, as a source and drain, regions 7 and 8 and, as a bulk, this lower bulk region. It should be understood that the upper bulk region must be sufficiently thin for the stored charges, attracted on the gate side, to have a sufficient electrostatic influence on the lower bulk region, which is why it has been indicated that this bulk region has a thickness preferably close to 10 nm.

Thus, a state 1 can be distinguished from a state 0 by the flowing or not of a current in a read phase. It should be noted that these two states are very well differentiated since, during the reading of a 0, absolutely no current flows between the drain and the source. Due to the total lack of current flow during the presence of a state 0, the device has a very long retention time since, even during the reading of a state 1, a slight loss of charges stored in the upper bulk region occurs, and there will always be a marked difference between states 0 and 1.

It should also be noted that, due to the fact that during the read state, only a slightly positive voltage is applied to the drain, there is no charge creation by impact in the lower bulk region 14 during a reading.

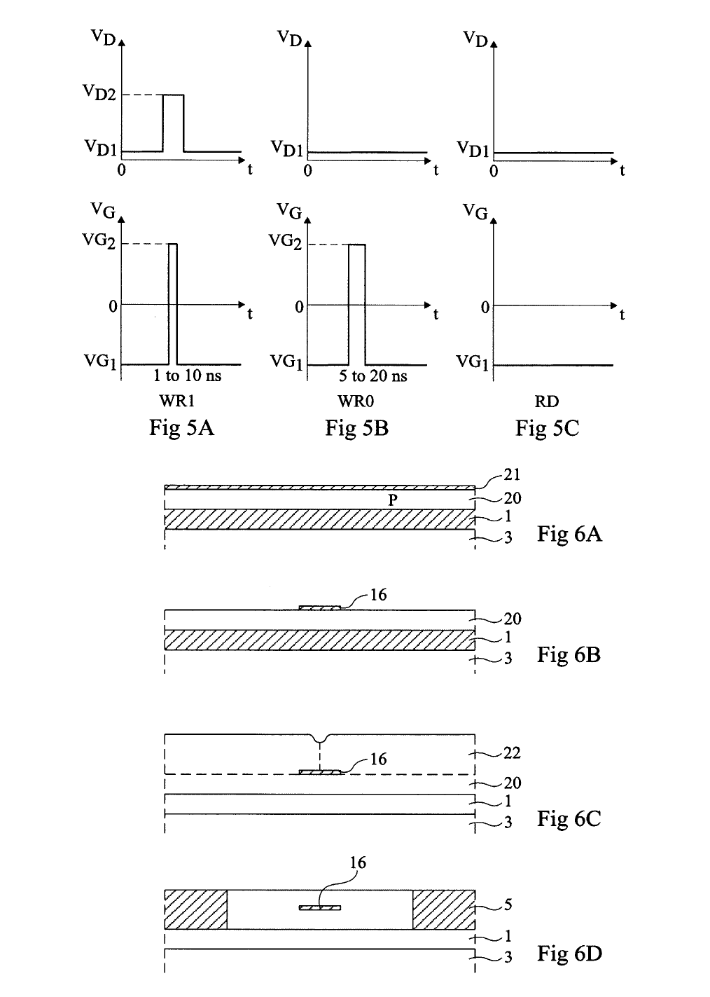

To better illustrate the memory cell operation, each of FIGS. 5A, 5B, and 5C shows the variation of the drain (VD) and gate (VG) voltages, respectively during states of writing of a 1 (WR1), of writing of a 0 (WR0), and of reading (RD). During the writing of a 1 (FIG. 5A), the drain voltage is made to vary from a zero or slightly positive voltage VD1, for example, 0.1 V, to a clearly positive voltage VD2, for example, from 1 to 2.2 V and, during the period (for example, from 5 to 30 ns) during which drain voltage VD2 is applied, the gate is briefly (for example, during from 1 to 10 ns) taken from a negative voltage VG1 to a positive voltage VG2, for example, from −1.2 volt to +1 volt. For the writing of a zero (FIG. 5B), the drain voltage is maintained at low value VD1 and the gate is taken for a short period, for example, ranging from 1 to 10 nanoseconds, to a positive value to enable to drain off charges that may be present in the upper bulk region. In the read or retention state (FIG. 5C), the drain is maintained at low voltage value VD1 and the gate is maintained at its negative value VG1.

The voltage application mode described in relation with FIGS. 5A to 5C is particularly advantageous since it only provides two possible voltage levels on the gate and on the drain. More complex voltage switching modes may however be provided in which, for example, the drain voltage would be switchable between more than two voltage levels, for example a third zero or negative voltage level during the phase of writing of a 0, or a zero voltage level during the retention phase. During phases of writing of a 1, instead of creating holes by impact ionization, other phenomena may be used. By applying a strongly negative voltage (for example, −2.5 V) to the gate, and a positive voltage to the drain, holes will be created by B to B tunneling or by activation of the parasitic bipolar transistor.

It should be noted that the voltage values indicated hereabove are purely indicative and are given for a memory cell substantially having the previously-indicated dimensions. It will be within the abilities of those skilled in the art to adapt these values to the specific characteristics of a specific component.

FIGS. 6A to 6D illustrate possible steps of the forming of a structure such as that in FIG. 1.

As illustrated in FIG. 6A, it is started from an SOI-type structure comprising, on a support 3 coated with an insulating layer 1, a lightly-doped P-type substrate 20 on which a thin insulating layer 21 is formed, for example, by thermal oxidation.

At the step illustrated in FIG. 6B, insulating layer 21 is etched to form separation layers 16 mentioned in the description of FIG. 1.

At the step illustrated in FIG. 6C, a lightly-doped P-type layer 22 is grown by epitaxy. In known manner, the epitaxy will develop from the apparent surface of layer 20 and will close up above layer 16. Preferably, this epitaxial growth is carried on to reach a greater thickness than the thickness desired for bulk region 13 and a thinning is performed to decrease this thickness.

Then, or during an intermediary step, as illustrated in FIG. 6D, insulating periphery 5 surrounding the desired active area is formed, after which the conventional steps of forming of a gate oxide, of a gate, and of the source-drain regions (not shown) are carried out.

What has been described hereabove is a possible example only of the forming of a structure of the type in FIG. 1. Other embodiments may be envisaged. For example, it may be started from a sandwich on insulator successively comprising a P-type silicon layer, a silicon-germanium layer, and a P-type silicon layer, the silicon-germanium layer having been shaped according to the dimensions of insulating layer 16, after which the silicon-germanium layer may be sub-etched and the cavity thus formed may be filled with an insulator. Wafer bonding techniques may also be used.

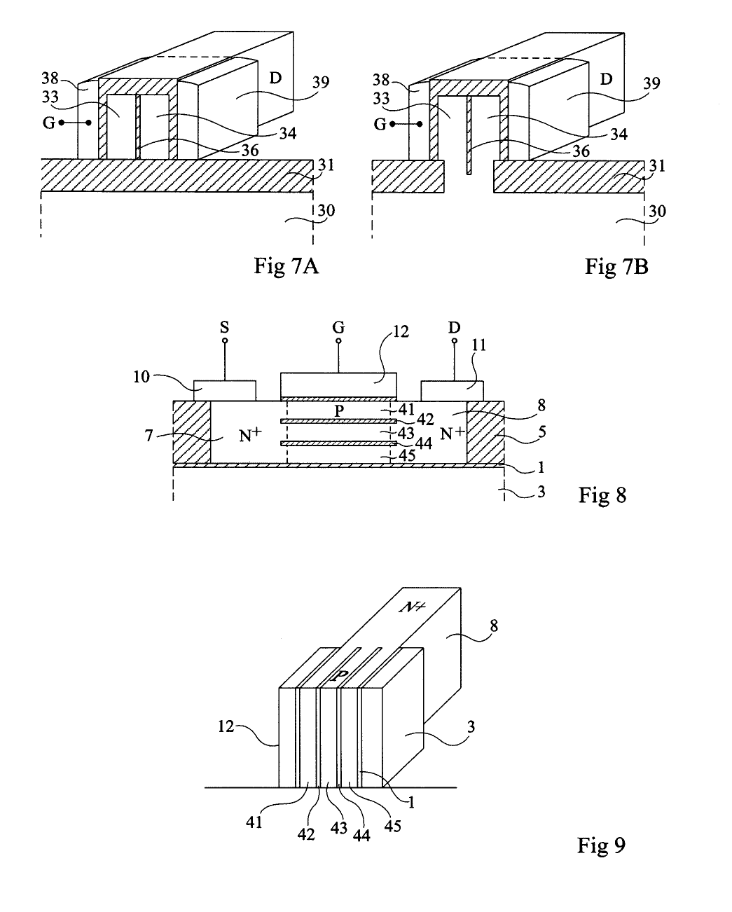

The above-described memory cell is capable of having many alterations and modifications. FIGS. 7A and 7B illustrate embodiments according to a configuration generally called FINFET structure (fin field-effect transistor) in the art. These drawings are cross-section and perspective views of the bulk portion and of the drain portion of the structure, the source portion, not shown, being at the front of the plane of the drawing. A fin silicon excrescence is formed above a wafer 30 coated with an insulating layer 31. This excrescence is divided in a left-hand portion 33 and a right-hand portion 34 respectively corresponding to upper bulk region 13 and to lower bulk region 14 of FIG. 1, the separation being provided by an insulator 36. Insulated gate metallizations 38 and 39 are arranged on either side of the fin, in front of left-hand bulk 33 and on right-hand bulk 34. In FIG. 7A, bulk regions 33 and 34 are insulated from wafer 30 by layer 31. In FIG. 7B, there is a continuity between bulk regions 33 and wafer 30. It should be understood that this structure operates in the same way as the structure of FIG. 1 if a single one of the two gates is used.

The two gates 38 and 39 may be used to selectively invert the functions of the left-hand and right-hand bulks. Similarly, in the structure of FIG. 1, it may be provided to selectively bias support 3 to act on lower bulk region 14 through insulating layer 1, for example, to adjust the threshold voltage of the lower transistor. A lower gate may also be added.

FIG. 8 shows another variation of the structure of FIG. 1. The same elements are designated with the same reference numerals. The transistor bulk, instead of having its thickness divided in two regions, is divided in three regions: an upper region 41 separated by an insulator 42 from a central region 43, itself separated by an insulator 44 from a lower region 45. Thus, provided to provide a possibility of biasing of support 3, a two-bit memory cell, that is, a four-state memory cell, is obtained. The upper gate enables, as described previously, to store or not charges in upper bulk region 41. The lower gate, corresponding to support region 3, enables to store or not charges in lower bulk region 45. A first state (11) is obtained if charges are stored in the upper and lower regions, a second state is obtained (00) if no charge is stored in the upper portion and in the lower portion, a third state (10) is obtained if charges are stored in the upper portion and not in the lower bulk region, and a fourth state (01) is obtained if charges are stored in the lower bulk region and not in the upper bulk region. The states (01) and (10) can be differentiated in various ways. In particular, if the upper or lower gates are different (different work function or different insulator thickness) and/or if the applied voltages are different, a variable amount of charges will be stored in the upper bulk region and in the lower bulk region for each writing of a 1. Thus, the four possible values of the current in the central bulk region can be well differentiated.

FIG. 9 very schematically shows a FINFET embodiment of the structure of FIG. 8. This drawing will not be described in detail, the elements having the same functions as those in FIG. 8 being designated with the same reference numerals.

Specific embodiments of the present invention have been described. Various alterations, modifications, and improvements will occur to those skilled in the art. In particular, many variations of the forming of MOS transistors may be adopted, for example, the forming of lightly-doped source and drain areas (LDD) in the vicinity of the channel region.

It should also be understood that the fact of having called state 1 one of the storage states and state 0 the other storage state is totally arbitrary.

The foregoing relates to a transistor having two bulks separated by a dielectric: a bulk capable of storing charges of a first biasing and a bulk capable of conducting charges of opposite biasing. There thus is no coexistence of charges of opposite biasing in a same bulk. This is one of the main reasons for which the described structure avoids the above-mentioned disadvantages of prior art single-transistor memory cells (limited retention time, high consumption, low differentiation between the two storage states, complexity of control, low operating speed, impossibility to decrease the thickness of the transistor bulk which must ensure the simultaneous presence of electrons and of holes). Further, the described device can operate with a single gate and it relatively simple to control.

Various embodiments and variations of a memory cell with a single transistor have been described herein. Those skilled in the art may combine various elements of these various embodiments and variations without showing any inventive step.

In particular, in the embodiment described in detail hereabove, the MOS transistor is insulated by an insulating layer 1. It may be provided for this MOS transistor to be directly formed above a silicon substrate of opposite conductivity type than the drain/source regions, that is, a P-type substrate if the drain/source regions are of type N.

Further, in the embodiment described in detail hereabove, lower portion 14 of the bulk region, under insulating layer portion 16, is of the same P conductivity type than upper portion 13. According to a variation, it may be of opposite conductivity type, that is, of type N. The doping level of lower portion 14 will then preferably be selected within a range from 10¹⁶ to 10¹⁸ atoms/cm³ according to its thickness so that this lower portion 14 is fully depleted at state 0 and that it contains enough available electrons at state 1. Then, during a holding state, if the memory cell is programmed to 0, N-type lower portion 14 of the bulk region will be depleted by the negative gate voltage and no current will be able to flow from the source to the drain through this portion. Similarly, in the embodiment of FIGS. 8 and 9, the N-type central region may be P-type doped in the same conditions.

1. A memory cell formed of a MOS transistor having a drain, a source, and a bulk region coated with an insulated gate, wherein the thickness of the bulk region is divided in two distinct regions separated by an insulated layer portion extending parallel to the gate plane.

2. The memory cell of claim 1, wherein the two distinct regions are of the same conductivity type.

3. The memory cell of claim 1, wherein the two distinct regions are of opposite conductivity types.

4. The memory cell of claim 1, formed from an SOI structure.

5. The memory cell of claim 1, formed from a FINFET structure.

6. The memory cell of claim 1, wherein the insulating layer portion has a thickness approximately ranging from 1 to 10 nanometers, preferably from 1 to 3 nanometers.

7. The memory cell of claim 1, wherein the bulk region closest to the gate has a thickness ranging from 5 to 50 nm, preferably from 5 to 20 nm.

8. The memory cell of claim 1, further comprising a second insulated gate under the bulk region.

9. The memory cell of claim 1, wherein the MOS transistor is insulated by an insulating layer.

10. The memory point of claim 1, wherein the MOS transistor is formed directly on a substrate having a conductivity type opposite to that of its drain/source.

11. The memory cell of claim 1, wherein the bulk region comprises a third region separated from the two above-mentioned distinct regions by an insulating layer portion extending parallel to the gate plane and substantially having the same extension as the insulating layer portion extending between the first two distinct regions, and wherein a second gate is arranged in front of the third distinct region, opposite to the first gate.

12. A method for using the memory cell of claim 1, wherein the source voltage is considered as the reference voltage and the source and drain regions are of type N, this method comprising, in any order, the steps of:
writing of a 1: application of a positive voltage to the drain and, during the application of this positive voltage, application of a short positive voltage to the gate,
writing of a 0: application of a very slightly positive, zero, or negative voltage to the drain and application of a positive voltage to the gate,
reading: application of a negative voltage to the gate and of a slightly positive voltage to the drain, and
holding: application of a negative voltage to the gate and of a slightly positive or zero voltage to the drain.

13. A method for using the four-state memory cell of claim 11, wherein the source voltage is considered as the reference voltage and the source and drain regions are of type N, this method comprising, in any order, the steps of:
writing of a state (11): application of a positive voltage to the drain and, during the application of this positive voltage, application of a short positive voltage to the two gates,
writing of a state (00): application of a very slightly positive, zero, or negative voltage to the drain and application of a positive voltage on the two gates,
writing of a state (01) or (10): application of a positive voltage to the drain and, during the application of this positive voltage, application of a short positive voltage to one of the gates, then application of a very slightly positive, zero, or negative voltage to the drain, and application of a positive voltage to the other gate,
reading: application of a negative voltage to the gates and of a slightly positive voltage to the drain, and
holding: application of a negative voltage to the gates and of a slightly positive or zero voltage to the drain.
